(19) United States
(12) Patent Application Publication
(10) Pub. No.: US 2007/0194367 A1
(43) Pub. Date: Aug. 23, 2007

(54) Storage node, nonvolatile memory device, methods of fabricating the same and method of operating the nonvolatile memory device

(75) Inventors: Chang-Wook Moon, Seoul (KR); Eun-Hong Lee, Seoul (KR); Choong-Rae Cho, Gimhae-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/706,995

(22) Filed: Feb. 16, 2007

(30) Foreign Application Priority Data
Feb. 17, 2006 (KR) 10-2006-015622

(51) Int. Cl. H01L 29/76

(52) U.S. Cl. 257/314

(57) ABSTRACT

Provided are a storage node, a nonvolatile memory device, methods of fabricating the same and a method of operating the nonvolatile memory device. The storage node may include a lower metal layer and a first insulation layer, an intermediate metal layer, a second insulation layer, an upper metal layer and a nano layer, which are sequentially stacked on the lower metal layer. The nonvolatile memory device may include a switching device and the storage node connected to the switching device.

### PRIORITY STATEMENT

This application claims priority under 35 U.S.C. § 119 to Korean Patent Application No. 10-2006-015622, filed on Feb. 17, 2006, in the Korean Intellectual Property Office (KIPO), the entire contents of which are incorporated herein by reference.

### BACKGROUND

1. Field

Example embodiments relate to a storage node, a nonvolatile memory device, methods of fabricating the same and a method of operating the nonvolatile memory device.

2. Description of the Related Art

Volatile memory devices (e.g., dynamic random access memory (DRAM) devices) may have a relatively high integration density, relatively low power consumption and a clearer manufacturing process. However, when power supply is cut off, volatile memory devices may lose all stored data. Conventional nonvolatile memory devices (e.g., flash memory devices) may have a relatively high erasure voltage, relatively low integration density and a relatively low operating speed. However, even if power supply is interrupted, conventional nonvolatile memory devices may not erase stored data.

As the Internet becomes more popular and Internet technology becomes more developed, useful and valuable information is increasing. To securely store the information, demand for memory devices having the advantage of volatile memory devices and nonvolatile memory devices increases. Nonvolatile memory devices (e.g., ferroelectric random access memory (FRAM) devices, magnetic random access memory (MRAM) devices, phase-change random access memory (PRAM) devices and/or resistance random access memory (RRAM) devices) are being developed.

The nonvolatile memory devices (e.g., FRAM devices, MRAM devices, PRAM devices and/or RRAM devices) may obtain the integration density of the DRAM devices, may have similar operation characteristics to the DRAM devices, and may retain stored data even if power supply is interrupted. Also, the nonvolatile memory devices (e.g., FRAM devices, MRAM devices, PRAM devices and/or RRAM devices) may be fabricated by conventional manufacturing processes of semiconductor memory devices. The FRAM devices, MRAM devices, PRAM devices, and RRAM devices may be different from one another in terms of the constitution of a storage node.

The storage node of the FRAM devices may include upper and lower electrodes and a ferroelectric substance. The storage node of the MRAM devices may include upper and lower magnetic layers and a tunneling film between the upper and lower magnetic layers. One of the upper and lower magnetic layers may be a pinned layer whose magnetic polarization may have a fixed direction, and the other may be a free layer whose magnetic polarization may have a direction identical and/or opposite to that of the pinned layer according to an external magnetic field.

The storage node of the PRAM devices may include upper and lower electrodes, a phase change layer between the upper and lower electrodes, and a lower electrode contact layer connecting the lower electrode and the phase change layer. The storage node of the RRAM devices may include upper and lower metal layers and an insulation layer (a resistance layer) between the upper and lower metal layers. The operation characteristics of nonvolatile memory devices may be determined by current-voltage characteristics of a material layer on which data is recorded in the storage node.

For example, the insulation layer of the storage node of RRAM devices may have different resistance characteristics according to an initially applied voltage. The different resistance characteristics may not change until an erasure voltage is applied even if the power supply is cut off. Although the RRAM devices have the characteristics of nonvolatile memory devices, they may have relatively low reproducibility, relatively high resistance deviation between cells, more easily damaged upper electrodes and may not be able to store multi-bit data, for example, conventional RRAM devices may record 1 bit data.

### SUMMARY

Example embodiments relate to a storage node, a nonvolatile memory device that may record multi-bit data, methods of fabricating the same and a method of operating the nonvolatile memory device.

According to example embodiments, a storage node may include a lower metal layer and a first insulation layer, an intermediate metal layer, a second insulation layer, an upper metal layer and/or a nano layer, which are sequentially stacked on the lower metal layer.

According to other example embodiments, a method of fabricating a storage node may include providing a lower metal layer and sequentially stacking a first insulation layer, an intermediate metal layer, a second insulation layer, an upper metal layer and/or a nano layer on the lower metal layer.

The first and second insulation layers may be aluminium oxide films. The upper metal layer may be a metal layer having a relatively low work function. The upper metal layer may be a gold (Au) layer. The nano layer may be one selected from the group consisting of a C₆₀ layer, C₇₀ layer, C₇₆ layer, C₈₆ layer, and C₁₁₆ layer.

According to other example embodiments, a nonvolatile memory device may include a switching device and the storage node of example embodiments connected to the switching device. According to other example embodiments, a method of fabricating a non-volatile memory device may include forming a switching device on a substrate and forming the storage node of example embodiments connected to the switching device via the lower metal layer.

According to other example embodiments, a method of operating the nonvolatile memory device may include maintaining the switching device turned on and applying a negative potential between the upper and lower metal layers.

The negative potential may be a write potential and is one of at least four different negative potentials. The method may further include applying a positive potential between the upper and lower metal layers after applying the negative potential. The positive potential may be a read potential. The data of 00, 01, 10, and/or 11 may be read by applying the positive potential between the upper and lower metal layers. The method may further include applying an erase potential between the upper and lower metal layers. The method may further include after applying the positive potential between the upper and lower metal layers and measuring a resistance of the nonvolatile memory device, comparing the measured resistance with a reference resistance.

### BRIEF DESCRIPTION OF THE DRAWINGS

Example embodiments will be more clearly understood from the following detailed description taken in conjunction with the accompanying drawings. FIGS. 1-4 represent non-limiting, example embodiments as described herein.

FIG. 1 is a diagram illustrating a nonvolatile memory device according to example embodiments; and

FIGS. 2, 3, and 4 are graphs illustrating operation characteristics (current-voltage characteristics) of the nonvolatile memory device illustrated in FIG. 1 according to example embodiments.

### DETAILED DESCRIPTION OF EXAMPLE EMBODIMENTS

A nonvolatile memory device and a method of operating the nonvolatile memory device according to example embodiments will now be described more fully hereinafter with reference to the accompanying drawings. Example embodiments disclose a storage node including a lower metal layer and a first insulation layer, an intermediate metal layer, a second insulation layer, an upper metal layer and a nano layer, sequentially stacked on the lower metal layer. However, example embodiments may include any combination of the above and are not limited to including a lower metal layer and a first insulation layer, an intermediate metal layer, a second insulation layer, an upper metal layer and a nano layer. In the drawings, the thickness of layers and regions are exaggerated for clarity.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” may encompass both an orientation of above and below. The device may be otherwise oriented (rotated 90° or at other orientations) and the spatially relative descriptors used herein interpreted accordingly.

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements and/or components, but do not preclude the presence or addition of one or more other features, integers, steps, operations, elements, components and/or groups thereof.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

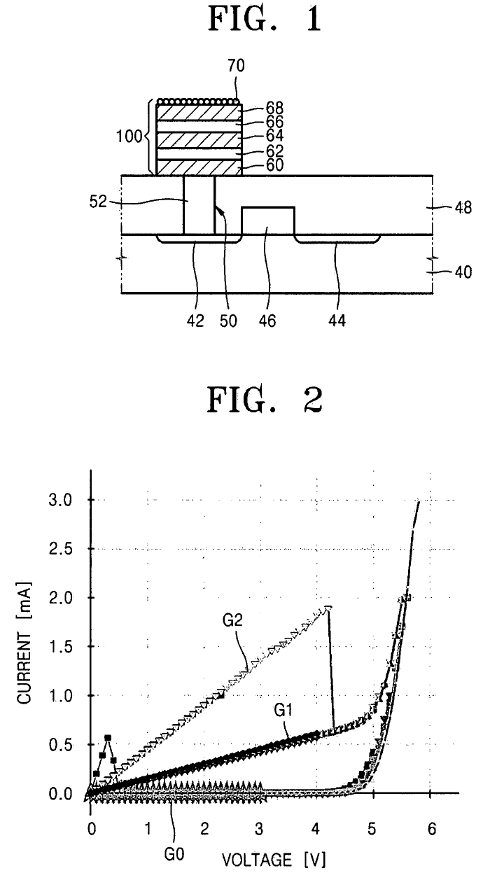

FIG. 1 is a diagram illustrating a nonvolatile memory device (hereinafter referred to as “memory device”) according to example embodiments. Referring to FIG. 1, first and second impurities regions 42 and 44, spaced apart from each other, may be formed on a substrate 40. The first impurities region 42 may be a P-type or N-type conductive impurities doped source and the second impurities region 44 may be a P-type or N-type conductive impurities doped drain. In example embodiments, the first and second impurities regions 42 and 44 include the same impurities.

A gate 46 may be disposed between the first and second impurities regions 42 and 44 on the substrate 40. The gate 46 and the first and second impurities regions 42 and 44 may be a switching device (e.g., a transistor). An interlayer insulation layer 48 may be formed on the substrate 40 and may cover the gate 46. A contact hole 50 may be formed in the interlayer insulation layer 48, through which the first impurities region 42 is exposed. The contact hole 50 may be filled with a conductive plug 52.

A storage node 100 may be formed on the interlayer insulation layer 48 and may cover the conductive plug 52. The storage node 100 may include a lower metal layer 60 that covers the conductive plug 52 and a part of the interlayer insulation layer 48 surrounding the conductive plug 52. The storage node 100 may include a first insulation layer 62, an intermediate metal layer 64, a second insulation layer 66 and/or an upper metal layer 68, which are sequentially stacked on the lower metal layer 60. The storage node 100 may include a nano layer 70 on the upper metal layer 68.

The upper metal layer 68 may be a metal layer having a relatively low work function, e.g., a gold (Au) layer. The first and second insulation layers 62 and 66 may be aluminum oxide films having a given thickness, e.g., Al₂O₃ film having a thickness of several nanometers. The nano layer 70 may be a Fullerene layer, for example, a C₆₀ layer, C₇₀ layer, C₇₆ layer, C₈₆ layer or C₁₁₆ layer. The resistance characteristics of the memory device including the storage node 100 will now be described with reference to the current-voltage characteristics.

If a given negative potential is applied between the upper and lower metal layers 68 and 60 of the storage node 100 of the memory device, e.g., a negative voltage is applied to the upper metal layer 68, and a positive voltage is applied to the lower metal layer 60, the memory device may have given current-voltage characteristics, which are changed according to the negative potential. If the negative potential applied between the upper and lower metal layers 68 and 60 are first and second negative potentials, the memory device may have different first and second current-voltage characteristics.

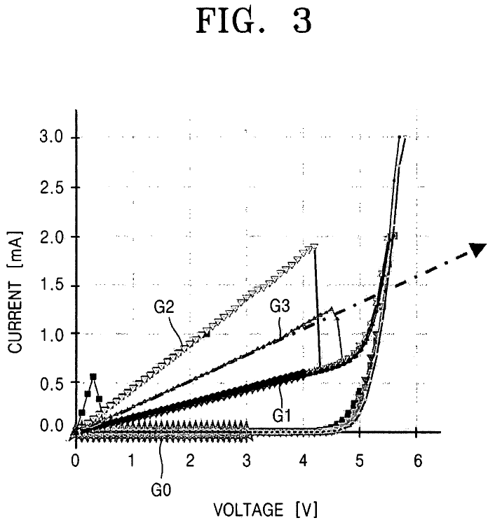

Examples of the different first and second current-voltage characteristics are illustrated in FIGS. 2 and 3. FIGS. 2, 3, and 4 are graphs illustrating operation characteristics (current-voltage characteristics) of the nonvolatile memory device illustrated in FIG. 1. Referring to FIG. 2, three graphs indicate three different current-voltage characteristics of the memory device. A first graph G1 indicates current-voltage characteristics of the memory device when a first negative potential may be applied between the upper and lower metal layers 68 and 60. A second graph G2 indicates current-voltage characteristics of the memory device when a second negative potential may be applied between the upper and lower metal layers 68 and 60.

The first negative potential may be a value when a measured current is a first current. The second negative potential may be a value when the measured current is a second current. The first current may be about −1.0 mA, and the second current may be about −2.0 mA. A base graph G0 indicates current-voltage characteristics of the memory device when an initial zero potential may be applied between the upper and lower metal layers 68 and 60.

In comparison with the base graph G0 and the first and second graphs G1 and G2, the memory device may have different current values at a given positive voltage, e.g., +3 V. The memory device may have different resistance values at the given positive voltage, for example, the memory device may have different resistance states at a single voltage. The different resistance states may be data states of the memory device.

Referring to FIG. 3, four graphs indicate four different current-voltage characteristics, e.g., four different resistance states, of the memory device. A third graph G3 indicates current-voltage characteristics of the memory device when a third negative potential may be applied between the upper and lower metal layers 68 and 60. The third negative potential may be a value when the measured current is a third current, e.g., about −1.5 mA. A base graph G0 and the first and second graphs G1 and G2 may be the same as descried with reference to FIG. 2. The memory device may have the four different resistance states and each of the resistance states may be a data state, so that the memory device may have four different data states. The four different data states may correspond to 00, 01, 10, and 11. The memory device may store 2 bit data.

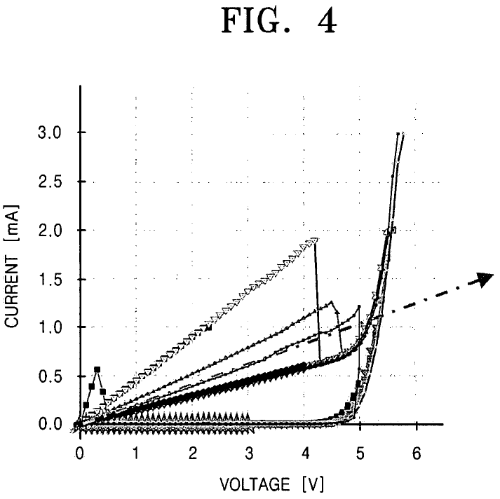

When a different negative potential is applied between the upper and lower metal layers 68 and 60, the memory device may have different current-voltage characteristics in the range of a positive voltage as illustrated in FIGS. 2 and 3. Because the memory device may have more than four different resistance states, it may record 2 bit data and more than 3 bit data. Referring to FIG. 4, five graphs indicate five different current-voltage characteristics, e.g., five different resistance states, of the memory device.

### Operation Method

### Write

Writing data to the memory device may make the memory device have one of the resistance states, for example, one of the four different current-voltage characteristics (resistance characteristics) illustrated in FIG. 3. A given negative potential may be applied between the upper and lower metal layers 68 and 60 of the storage node 100 with the switching device of the memory device, e.g., the transistor turned on. Because the memory device may have four different resistance states according to the negative potential, one of the 2 bit data, e.g., 00, 01, 10, and 11, may be written to the memory device. To write more than 3 bit data to the memory device, one of eight different negative potentials may be applied between the upper and lower metal layers 68 and 60 of the memory device. Multi-bit data, with more than 3 bit data, may be written to the memory device.

### Read

A process of reading the memory device may measure the resistance state of the memory device. If the memory device has four different current-voltage characteristics (resistance states) as illustrated in FIG. 3, a positive read potential may be applied between the upper and lower metal layers 68 and 60 of the storage node 100 with the switching device turned on.

To read the four different resistance states of the memory device, the positive read potential may be lower than a potential used to return the resistance states of the memory device to an initial state. The positive read potential may be between about 0 V and about 4 V. When the positive read potential is about 3 V and the resistance state read from the memory device, e.g., the current-voltage characteristic, follows the base graph G0, it may be 00 that is read from the 2 bit data of the memory device.

When the resistance state read from the memory device follows the first graph G1 at the same positive read potential, it may be 01 that is read from the 2 bit data of the memory device. When the resistance state read from the memory device follows the third graph G3 at the same positive read potential, it may be 10 that is read from the 2 bit data of the memory device. When the resistance state read from the memory device follows the second graph G2 at the same positive read potential, it may be 11 that is read from the 2 bit data of the memory device.

### Erase

A process of erasing the memory device may be to change the resistance state of the memory device to an initial resistance state. In detail, referring to FIG. 3, the process of erasing the memory device may be to change the current-voltage characteristics of the memory device as that of the base graph G0.

To erase data written to the memory device, an erase potential, e.g., a positive potential of more than about 4.5 and higher than the read potential, may be applied between the upper and lower metal layers 68 and 60 of the storage node 100 with the switching device of the memory device turned on. As described above, because the memory device of example embodiments may have at least four different resistance states, the memory device may store multi-bit data more than 2 bit data.

While example embodiments have been particularly shown and described with reference to example embodiments thereof, it will be understood by those of ordinary skill in the art that various changes in form and details may be made therein without departing from the spirit and scope of the following claims.

What is claimed is:

1. A storage node comprising:
a lower metal layer; and
a first insulation layer, an intermediate metal layer, a second insulation layer, an upper metal layer, and a nano layer, which are sequentially stacked on the lower metal layer.

2. A non-volatile memory device comprising:
a switching device; and
the storage node of claim 1 connected to the switching device via the lower metal layer.

3. The storage node according to claim 1, wherein the first and second insulation layers are aluminium oxide films.

4. The storage node according to claim 1, wherein the upper metal layer is a metal layer having a relatively low work function.

5. The storage node according to claim 4, wherein the upper metal layer is a gold (Au) layer.

6. The storage node according to claim 1, wherein the nano layer is one selected from the group consisting of a C₆₀ layer, C₇₀ layer, C₇₆ layer, C₈₆ layer and C₁₁₆ layer.

7. A method of fabricating a storage node comprising:
providing a lower metal layer; and
sequentially stacking a first insulation layer, an intermediate metal layer, a second insulation layer, an upper metal layer, and a nano layer on the lower metal layer.

8. A method of fabricating a non-volatile memory device comprising:
forming a switching device on a substrate; and
forming the storage node of claim 7 connected to the switching device via the lower metal layer.

9. The method according to claim 7, wherein forming the first and second insulation layers includes forming aluminium oxide films.

10. The method according to claim 7, wherein forming the upper metal layer includes forming a metal layer having a relatively low work function.

11. The method according to claim 10, wherein forming the upper metal layer includes forming a gold (Au) layer.

12. The method according to claim 7, wherein forming the nano layer includes forming one selected from the group consisting of a C₆₀ layer, C₇₀ layer, C₇₆ layer, C₈₆ layer and C₁₁₆ layer.

13. A method of operating the nonvolatile memory device of claim 2, the method comprising:
maintaining the switching device turned on; and
applying a negative potential between the upper and lower metal layers.

14. The method according to claim 13, wherein applying the negative potential includes applying a write potential and the negative potential includes one of at least four different negative potentials.

15. The method according to claim 13, further comprising:
applying a positive potential between the upper and lower metal layers after applying the negative potential.

16. The method according to claim 15, wherein applying the positive potential includes applying a read potential, thereby reading data with a value of 00, 01, 10, or 11.

17. The method according to claim 13, further comprising:
applying an erase potential between the upper and lower metal layers.

18. The method according to claim 15, further comprising:
after applying the positive potential between the upper and lower metal layers and measuring a resistance of the nonvolatile memory device, comparing the measured resistance with a reference resistance.
